(19) United States
(12) Patent Application Publication
(10) Pub. No.: US 2025/0038155 A1
(43) Pub. Date: Jan. 30, 2025

(54) ELECTRONIC DISPLAY DEVICE OF EMISSIVE PIXEL SCREEN TYPE, FOR AN AIRCRAFT COCKPIT

(71) Applicant: THALES, MEUDON (FR)

(72) Inventors: Vincent TORAILLE, MERIGNAC (FR); Thierry KRETZ, MERIGNAC (FR)

(21) Appl. No.: 18/782,084

(22) Filed: Jul. 24, 2024

(30) Foreign Application Priority Data
Jul. 28, 2023 (FR) 2308198

(51) Int. Cl. H01L 25/075; G08G 5/00; H01L 33/32; H01L 33/50; H01L 33/52

(52) U.S. Cl. CPC H01L 25/0753; G08G 5/0021; H01L 33/32; H01L 33/502; H01L 33/52

(57) ABSTRACT

A screen based on emissive pixels for an aircraft cockpit, including a flat substrate bearing a plurality of electroluminescent diodes in the same emission spectrum and wherein each pixel is made up of at least one compact group of several of the electroluminescent diodes. In a pixel of the screen, the electroluminescent diodes of one of the groups are covered with a layer forming a cover common to the electroluminescent diodes of the group and relaying a diffuse light, with or without photoluminescence, in response to the emission of light by the electroluminescent diodes of the group.

### CROSS-REFERENCE TO RELATED APPLICATION

This application claims priority to foreign French patent application No. FR 2308198, filed on Jul. 28, 2023, the disclosure of which is incorporated by reference in its entirety.

### FIELD OF THE INVENTION

The invention relates to the field of colour display screens for the aeronautical sector, and more specifically for aircraft or helicopter cockpits, as well as to their design, and their evolution over the service life—which is particularly long—of a given model of aircraft.

### BACKGROUND

Of particular interest are screens for the flight deck—or cockpit—of an aircraft-aeroplane or helicopter-civil or military, measuring 3″, 10″ or 15″ on the diagonal, for example, these dimension values being mentioned purely as examples. These screens are used for navigation, cartography, displaying the attitude indicator, or taxiing, in particular, but other applications exist and may be envisaged, including 20″ screens. Compared to screens for use by the general public, these aeronautical screens must be able to withstand more demanding operating environments, such as high temperatures (75° C.), low temperatures (−40° C.), with potentially rapid temperature fluctuations, of up to several dozen degrees ° C. in one minute. It must also be possible to store these screens, when not being used, at temperatures ranging from −55° C. to +85° C. They must be able to withstand very long exposure to ionizing radiation such as the radiation found at the altitudes at which aeroplanes fly, for example 10000 m above sea level, or even higher. They must have a service life of several dozen years and therefore be somewhat immune to breakdown, either because they never break down, or because redundancy systems take over from components that are experiencing problems. Performance in terms of brightness must also be stable over the service life in question. Manufacturing technologies are therefore adapted to these requirements, both as regards the selection of materials, the frame, the electrical and mechanical dimensioning, the choice of design of electrical circuits, and the choice of basic components. The screens in question may be placed in an LRU-line replaceable unit-having a specific function, or may form part of an integrated architecture, in an avionics suite.

These screens are often based on LCD (liquid crystal display) technology. LCD screens make use of the variable bi-refringence properties of crystals, the orientation of which is varied as a function of an electrical field. They are permanently backlit, in recent years by white LEDs, that is light-emitting diodes (but historically by CCFL-Cold Cathode Fluorescent Lamps—which are still commonly used), and depending on the orientation of the liquid crystals, the light is intermittently transmitted or not transmitted since the liquid crystal is placed between two crossed polarizers. The white LEDs may consist of blue LEDs on which a luminophore referred to as a yellow phosphor has been deposited (often YAG: Ce3+), which by fluorescence and the addition of the blue from the diode not absorbed by the phosphor and of the yellow produced by fluorescence, produces the white.

These are TFTs (thin film transistors) allowing voltage control of the liquid crystals that define the pixels. To obtain colour, use is made of three liquid crystal cells per pixel, each having, parallel to the liquid crystal, a red, green or blue filter, making it possible, by lighting up one or more of them, to obtain the desired colour, by additive colour synthesis. These filters are passive filters, which absorb (and in any case prevent the transmission of) certain wavelengths, while allowing other wavelengths to pass through, in general by a phenomenon of straight line transmission.

The backlighting LEDs, which may be between 2 and 3 mm wide, may naturally carpet the background, but may also be placed along the side (in a configuration referred to as “edge-lit”), with a planar waveguide for example made of PMMA (polymethyl methacrylate or Plexiglas), loaded through its volume for diffusion across the plane or having at the surface screen-printed diffusing dots, for example. The backlighting LEDs are permanently lit up.

LCD screen technologies, based on the transmission and the concealment of a light permanently present in the background, face competition from technologies wherein monochrome or coloured light is emitted by LEDs, which are lit up and switched off so as to produce the image—this is referred to as self-emissive or emissive pixels.

Thus, for example, OLED screens, without liquid crystals and without permanent backlighting, are widely used in devices for the general public, for example in smartphones—the pixels may be 150 μm for example. OLEDs, or organic LEDs, having a dimension of the order of magnitude of a pixel, are formed by superposition of several organic semiconductor layers.

OLEDs may be placed in groups of LEDs of different colours, namely a red, a green and a blue, and it is possible to switch them all off at the same time so as to obtain a deep black. The colour may be obtained natively by adapting the chemistry of the OLED so as to obtain a given colour or, if the OLEDs emit a white light, by the use of passive filters which absorb wavelengths other than those to be kept for the LED in question. It is also possible, in recent models, to shift the emission wavelength by virtue of a quantum dot, which is a tiny physico-chemical structure-semiconductor nanocrystals-capable of photoluminescence or more specifically of fluorescence in a narrow spectral range.

The service life of OLED products currently appears to be insufficient for aeronautical applications, in particular owing to the organic nature of the material of the OLEDs.

Moving forwards, micro-LEDs are a recent development, being on the one hand smaller (as small as 50 μm in width, or even less), using in particular indium gallium nitride InGaN semiconductors and gallium nitride GaN semiconductors, and offering interesting possibilities for the aeronautical field, with service lives expected to be high, very short response times, of the order of a few nanoseconds, and low power consumption. Micro-LEDs are controlled by CMOS circuits on silicon or by TFTs and can also be found on PCBs. A current command is transmitted to them via these control circuits.

Micro-LEDs do not heat up very much, are very bright and have a short response time. Their service life is also advantageous. Manufacturing methods use the deposition of materials on glass or silicon wafers, by epitaxy, with dimensions of less than 50 μm, then the transfer (mass transfer) onto a CMOS matrix (for example) of certain micro-LEDs thus manufactured.

Micro-LEDs may be placed in groups of three colour micro-LEDs each having one of three colours, Red (maximum emission towards around 630 nm), Green (maximum emission towards around 570 nm) and Blue (maximum emission around 450 nm), or RGB in the visible spectrum, close to one another in a horizontal arrangement, vertical arrangements also existing. Just as they are lit up separately from one another, it is also possible to switch them off simultaneously, which then provides a deep black and, ultimately, contrast is good.

To obtain these colour micro-LEDs, micro-LEDs which are natively of different colours are envisaged, by adjusting the nature and/or the thickness of the semiconductor layers of the stack. Use may also be made of natively blue micro-LEDs, known for their energy efficiency and in particular for being more energy efficient than red micro-LEDs and green micro-LEDs, with, for two micro-LEDs out of three, an active, photoluminescent, generally fluorescent, element possibly of quantum dot type, for generating, from the blue, either green or red depending on the size of the quantum dot, in both cases with a line width that is also quite small, 20 to 30 nm at mid peak.

For the cockpits of current aircraft fleets, prospects as regards evolution of the display are very poor or inexistent, since crews must have the same experience on each apparatus, and safety regulations, together with the cost of a possible simultaneous change on a large number of apparatus in circulation, do not open the way for any change.

The replacement of the LCD screens (with CCFL or LED backlighting) of apparatus in circulation, as and when maintenance is carried out, for example following a rare breakdown or during preventive maintenance, must be carried out in such a way that crew members are not faced with a change in how they perceive these screens.

Thus, since the apparatus are equipped with LCD screens with a given resolution, it is not really envisaged to replace them with emissive pixel screens of higher resolution, even though the latter offer various advantages and can come at a competitive cost. Moreover, it may be that it is not desired to change the resolution of video streams circulating between equipment, which in principle makes the installation of a screen with a higher resolution pointless.

However, the installation of screens based on emissive technology may nonetheless be unavoidable, owing to the scarcity or indeed unavailability of sources of supply for all or some screens based on transmissive technology. In the same vein, and without even getting as far as the unavailability of stocks of transmissive technology screens, emissive technology screens may also become less expensive than transmissive technology screens, which justifies efforts to integrate them into existing aircraft, or into new versions of models certified many years ago, certification having been performed with transmissive technology screens.

In general, there is demand for solutions for the evolution of existing products that require only a few modifications to the structural principles from one evolution of the product to the next, so as to easily meet the needs of the market or users.

It is also desirable for the products proposed to be easy to keep operational even in the event of failure of one diode out of a great many diodes, and there is therefore demand for solutions to get around such a failure, without modifying the product.

### SUMMARY OF THE INVENTION

In this regard, the invention provides a solution for providing solutions for maintenance of the apparatus in circulation based on LED screen emissive technology.

To provide a suitable service, there is proposed a screen based on emissive pixels for an aircraft cockpit, comprising a flat substrate bearing a plurality of electroluminescent diodes in the same emission spectrum, for example blue micro-LEDs, and wherein each pixel is made up of at least one compact group of several of said electroluminescent diodes.

This device has the particularity that in a pixel of the screen, the electroluminescent diodes of the group are covered with a layer forming a cover common to said electroluminescent diodes of said group and relaying a diffuse light, with or without photoluminescence, in response to the emission of light by the electroluminescent diodes of the group. In general, there is a cover for each group: the cover is specific to the group in question.

By virtue of these features, use is made of products already available, namely micro-LEDs or any LEDs of small size, and wider pixels are formed that are compatible with the environments of the aircraft cockpits for which they are intended, and which, as mentioned above, make the modification of the resolution compared to previous technologies difficult and more expensive, if not in fact impossible. Energy consumption is lowered, since screens based on emissive technology consume less power than screens having the same brightness but based on transmissive technology. Product reliability is improved, with redundancy in the light sources, since each group of diodes, forming either a pixel or a sub-pixel of a given colour, is made up of several diodes which, if one fails, may be used to keep the product in operation at just as good a level, by increasing the power communicated to the diodes of the group which are not defective.

This thus represents a significant advance in the area of display screens (colour or monochrome) for the aeronautical sector, since it is now also possible to install a screen based on emissive pixels in various aircraft cockpits, on the basis of a supply of substrates of micro-LEDs of very small, constant pitch, potentially dictated by a supplier or by supply conditions, and having screen resolutions that are nevertheless different since all that is required is to adapt the extent of the layers forming a cover in the two dimensions of the plane of the screen.

According to optional, advantageous features,
the layer may comprise quantum dots such that the light diffused has a greater wavelength than the light received from the electroluminescent diodes and that the layer has an angularly extensive light emission.

Thus, advantage is taken of two properties of quantum dots: they change the wavelength of the light by absorbing the incident light and by emitting a light of greater wavelength, and they emit this new light in a wide solid angle—it is therefore a light of modified wavelength and directionality which is relayed by the cover, by virtue of the quantum dots.
the pixel may comprise several groups of electroluminescent diodes, and for each group of the pixel, a layer with a specific colorimetric property (in particular, photoluminescent or not) covers the electroluminescent diodes of said group, forming a cover specific to each of the groups. Display by additive colour synthesis may then be achieved, which opens the door to a wide variety of colours.
the layer of one of said several groups of electroluminescent diodes may comprise a diffusing load and be without the property of photoluminescence. In this case, the cover diffuses a light of the same colour as the diodes, that is, in general a blue light.
the pixel may comprise a red group, a green group and a blue group. The red and green groups are formed by the presence of quantum dots selected so as to fluoresce a red light and a green light, respectively, in the covers associated with the groups in question.

The screen may thus be a colour screen offering a very wide range of colours by additive colour synthesis of green, red and blue groups. The groups of the three colours are formed by the association, for each of them, of a cover layer with the underlying diodes so as to provide the desired colour.

However, the screen may also be a monochrome screen of a flight control unit, green if each pixel comprises a single group, and the associated cover layers provide, by association with the underlying diodes, a green light.
the electroluminescent diodes may be diodes based on gallium nitride, referred to as micro-LEDs. They have a low energy consumption and a long service life.
the electroluminescent diodes may be blue diodes, which are particularly energy-efficient.
each group of diodes may be formed by bringing together square substrates of electroluminescent diodes comprising nine diodes in three rows of three diodes, and more generally, each group may be formed by bringing together rectangular substrates of electroluminescent diodes comprising diodes in several rows.
a material having a high optical density may be placed between the groups of diodes, which prevents illumination of a cover by the diodes of the neighbouring cover.
the colour layer may have been deposited by ink jet or screen printing, or other methods,
the colour layer may encapsulate the diodes, or be placed on a layer of glass adhesively bonded to the diodes.
the layer forming a cover may comprise quantum dots or phosphors so as to define its colour, which is compatible with the fact that all the diodes may be of the same nature, the wavelength of their light being modified by the layer forming a cover.
the layer may comprise phosphor granules or quantum dots, and each pixel may also comprise a group of several controlled electroluminescent diodes covered with an essentially non tinted diffusing layer common to said several electroluminescent diodes of the group, which makes it possible to diffuse the native light of the electroluminescent diodes, which are for example blue diodes.

The invention also proposes a method for replacement of a display screen of a flight deck of an aircraft, comprising a step of removing a screen, for example based on liquid crystals with backlighting, and a step of replacing said screen with a screen of resolution identical to the resolution of said liquid crystal screen.

The method is remarkable in that the screen of identical resolution is selected as a screen based on emissive pixels according to the preceding principles, the number of electroluminescent diodes in the groups being selected such that, given the number of groups, the size of the pixel is the size of the pixels of the screen based on liquid crystals with backlighting.

Thus, there is a change of technology, affording the advantages of diodes, including first of all micro-LEDs, but retaining the resolution of the old screen, and this makes it possible to satisfy the requirements of the user companies, manufacturers and regulators. This remarkable result is obtained thanks to the layers forming a cover which are common to the diodes of a group, the fact that there are at least two diodes per group, and the fact that the covers relay a diffuse light.

The invention also provides a method for industrialization of an aircraft, comprising a step of regulatory qualification carried out when a version of the aircraft for qualification purposes is equipped with a screen based on liquid crystals with backlighting, and a subsequent step of fitting, in a version of the aircraft for delivery for operation, a screen with a resolution identical to the resolution of said liquid crystal screen, this screen having undergone a qualification process itself. The screen of identical resolution is selected as a screen based on emissive pixels according to the invention, the number of electroluminescent diodes in the groups being selected such that, given the number of groups, the size of the pixel is the size of the pixels of the screen based on liquid crystals with backlighting. In general, the invention also makes it possible to give the designer flexibility when coming up with a new design.

Also proposed is a method for adapting a display screen of a cockpit of an aircraft according to the invention. It comprises a step of mapping the potential luminous power of the screen on the date of adaptation, which may be immediately after the manufacture of the module, then, as a function of the areas of lower luminous power identified on the screen, modifying the control of the screen by increasing the power emitted by the diodes of one of said groups of diodes of the screen corresponding to an area of lower luminous power, in order to compensate for a weakness in one of the diodes of said group by the other diodes in the group. Conversely, it is also possible to reduce the power of stronger diodes. Thus, the solution makes it possible to manage the case of a given micro-LED which has failed by adjusting the other micro-LEDs in its group. This may be carried out at the factory when calibrating the screen, or subsequently, during maintenance. Thus, the invention makes it possible to use redundancy of LEDs in the event of failure of an individual component. A colour pixel is in fact based on several micro-LEDs, which makes it possible to manage the failure of a given micro-LED, by deliberately increasing the luminous power generated by the others, so as to compensate for the power lost as a result of the failure.

### BRIEF DESCRIPTION OF THE DRAWINGS

The invention will be understood more clearly and other advantages will appear on reading the description below, which is not intended to be limiting, and by virtue of the attached figures in which:

FIG. 1 is a view of an initial arrangement of micro-LEDs according to two embodiments of the invention.

FIGS. 2A and 2B are views in cross section of one of the embodiments of FIG. 1, in two variants.

FIG. 3 depicts a variant embodiment.

FIGS. 4 and 5 depict two methods according to the invention.

### DETAILED DESCRIPTION

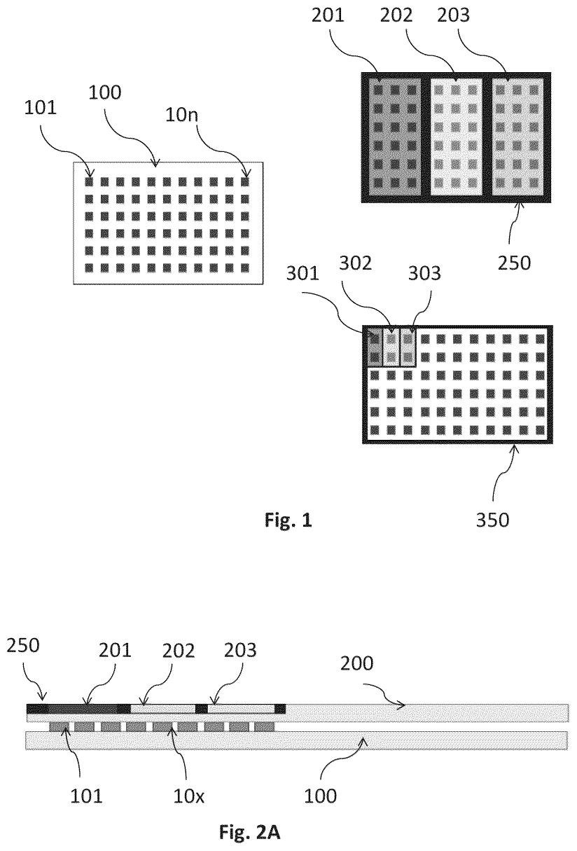

FIG. 1 depicts a support 100, which is a flat, rigid or semi-rigid object with two faces, of constant thickness (or flat substrate) bearing micro-LEDs 101, . . . 10n arranged as a rectangular grid, or a checkerboard, on one of its faces. The micro-LEDs 101, . . . 10n have a square geometry, seen from above. They are separated from one another by a distance which is of the same order of magnitude as their dimension, or slightly smaller. In the figure, the micro-LEDs 101, . . . 10n number, in a rectangular grid arrangement, 11 by 6, that is 66 micro-LEDs. They are blue micro-LEDs, known for having good energy efficiency. They emit a light with a relatively narrow wavelength peak, creating this blue colour.

The micro-LEDs 101, . . . 10n have been deposited on the surface of the support 101 by mass transfer, involving laser cutting them from an initial substrate, then transferring them from the initial substrate, by means of a separation layer and an elastomer buffer or another mass transfer solution. Each micro-LED may have a side of the order of 100 μm, and be separated from the next one, in the direction of alignment, by a space of 100 μm.

FIG. 1 proposes two ways of using the support 100, by depositing, on the face which bears the micro-LEDs, plates which, for some of the micro-LEDs, convert the luminous power of the blue micro-LEDs into luminous power with another wavelength peak, corresponding to a green or red light, in particular.

In a first embodiment, shown in the top right part of the figure, rectangular plates 201, 202 and 203 are selected to cover 3×6 micro-LEDs (compact rectangular arrangement) and they are placed on the support 100, one beside the other, and when seen from above as proposed in the figure, separated by a deposit of material having a high optical density (referred to as a black matrix). Two rows of 6 micro-LEDs are covered, incidentally, by the material having a high optical density.

The plate 201 is, in one embodiment, a cover based on synthetic resin loaded with red quantum dots (although, as regards loading, less sophisticated solutions are possible, in particular the use of phosphors), uninterrupted and homogeneous above the 3×6 micro-LEDs that it covers. The plate 202 is a cover also based on synthetic resin loaded with green quantum dots (or optionally phosphors), also uninterrupted and homogeneous above the 3×6 micro-LEDs that it covers. The plates 201 and 202 have, by virtue of their nature and their small thickness, a function of transmission of luminous power, and by virtue of their chemical or physico-chemical load, a function of modification of the spectrum of the light by concentrating the latter around a particular wavelength. As it has been chosen to use quantum dots, they are therefore photoluminescent components. They also have, by virtue of their structure based in particular on a diffusing configuration and arrangement of the quantum dots in the cover, a function of diffusion of the light transmitted, which has the consequence that their surface above the spaces between two micro-LEDs is substantially as much a source of diffuse light transmitted as their surface directly above a given micro-LED, with an angular distribution which is also similar, and ideally uniform. The micro-LEDs that it covers cannot be distinguished individually by the observer, their light intensity being diffuse and distributed over the whole surface of the plate 201 or of the plate 202. Thus, the micro-LEDs are relayed by the associated cover, which modifies the spectrum of the light and diffuses the light angularly. The micro-LEDs are essentially a source of luminous power and their light is relayed by the cover.

The quantum dots behave as sources and emit in all directions, randomly.

In the blue coloured sub-pixel, the light is not emitted by photoluminescence but by an electroluminescent diode mechanism, which acts in a preferred direction.

Macroscopically, the light from the green and red sub-pixels is thus diffuse whereas the blue may be directional. So as to ensure that the resulting blend of colours perceived does not depend on the viewing angle, it has been chosen to make the blue sub-pixel diffuse, just like the green and red sub-pixels.

The plate 203 is uninterrupted and homogeneous above the 3×6 micro-LEDs that it covers and is formed of a diffusing material—again based on a synthetic resin, for example the same synthetic resin as used for the plates 201 and 202—this time without photoluminescent load—it does not modify the wavelength spectrum and thus keeps the blue emitted by the micro-LEDs unchanged—which is selected such that the surface above the spaces between two micro-LEDs is substantially as much a source of diffuse light transmitted as the surface directly above a given micro-LED, and again with an angular distribution which is also similar, and ideally uniform. Thus, the micro-LEDs are relayed by the associated cover, which angularly diffuses the light and this time keeps its spectrum essentially unchanged.

The plates 201, 202 and 203 are preferably structured such that the angular diffusion is similar or even the same (the aim is to get close to an orthotropic light source or Lambertian light source). The plate 203 therefore allows a blue light to pass through, like that of the underlying micro-LEDs, but the light it emits is more diffuse and uniform over a larger surface area than the light emitted by a single micro-LED, and the micro-LEDs that it covers cannot be distinguished individually by the observer, their light intensity being diffuse and distributed over the whole surface of the plate 203.

The assembly formed by the three plates 201 to 203 and the micro-LEDs that they cover constitutes a controllable colour pixel, since the three colours formed make it possible, in combination, to obtain all the colours of the visible by additive colour synthesis, and the 66 micro-LEDs are therefore controlled in such a way as to provide the colour and the brightness desired for a pixel of this size, which corresponds to a sub-optimal resolution given the small size of the micro-LEDs, but which may be entirely similar to the resolution obtained with older technologies, such as backlit LCD screens.

In a second embodiment, shown in the bottom right part of the figure, covers made up of rectangular plates 301, 302 and 303 are selected to cover 1×2 micro-LEDs (compact rectangular arrangement) and they are placed on the support 100, one beside the other, separated, when seen from above, by a thin deposit of the material having a high optical density (referred to as a black matrix) 350, this material again surrounding the support around the 66 LEDs. As a result of this arrangement, a pixel able to achieve a blend of the three colours is made up of six micro-LEDs, arranged in 2×3 layout. The support 100 has room to install nine pixels, occupying a space 9×6.

The diodes are controlled by variation of intensity or pulse-width modulation so as to ultimately modify an average power over a unit of time.

The material having a high optical density makes it possible to ensure that when the micro-LEDs associated with a given colour are lit up, their light does not bleed into the neighbouring cover, associated with another colour. In the hypothesis in which the material having a high optical density is placed vertically with respect to some micro-LEDs, which is the case of the arrangement in the top right of FIG. 1, in one embodiment, the micro-LEDs concealed are not commanded and remain off.

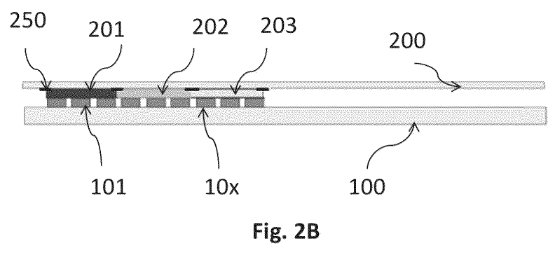

FIG. 2A shows an example of the production of the structures of FIG. 1. As shown in this figure, the micro-LEDs are present on the surface of the support 100, and a sheet of glass 200 is laid on the micro-LEDs, the plates 201 and 202 being installed in the thickness or on the surface of this glass, each plate constituting a photoluminescent cover, and the plate 203 constituting a diffusing cover, and these covers may be thin, in particular thinner than the sheet of glass 200. The plates 201 and 202 are deposited for example by ink jet or screen printing a polymer or a synthetic resin in which the quantum dots (or “phosphor” compositions) are mixed. The plate 203 is deposited for example by the same method, in the form of a deposit of a synthetic resin or of a polymer which is initially fluid and contains a diffusing powder.

A material having a high optical density 250 fills the spaces between the zones forming the sub-pixels and thus conceals metallization and the substrate present between the micro-LEDs. It may also take the form of a synthetic resin or of a polymer, comprising a black or very dark pigment.

Nevertheless, the material having a high optical density 250 may be a metal deposit, without resin or polymer, in which case it may be deposited in the form of a metal oxide by spraying or evaporation, in particular before the deposition by inkjet printing of the plates 201, 202 and 203. It is then thinner than the layers of resin or polymer. It may in particular comprise chromium or molybdenum oxide.

The deposition of the three plates 201, 202 and 203 and of the material having a high optical density is carried out for example in a single thinned rectangular surface of the sheet of glass. In this figure, the covers formed of the plates 201 and 202 and the cover formed of the plate 203 are present on the face of the sheet of glass 200 which is turned away from the LEDs 101 . . . 10x, but it is also possible for the covers, while deposited on the sheet of glass 200, to be present on the face thereof which is turned towards the LEDs 101, . . . 10x, and to thus come, at the time of assembly, into contact with the outer face thereof. In any case, the deposition of the covers and of the material having a high optical density is in this variant carried out on a continuous flat surface of the plate of glass, but the plate of glass may also optionally have reliefs, while being generally without holes.

Variants are also implemented as an alternative to this structure.

In FIG. 2B, the colour component has been deposited on the upper part of the diodes. The sheet of glass has received the material having a high optical density 250, and is laid on the assembly made up of the diodes and of the covers. More specifically, as the covers are formed of a polymer or of a synthetic resin, they are deposited on top of the diodes, although there are empty spaces between the diodes. The viscosity and the thickness of the material deposited is sufficient for the material deposited to form a continuous layer forming bridges from the top of one diode to the top of the next diode, and for the layer to be homogeneous and flat despite the relief on which it has been deposited

The material having a high optical density 250 has for its part been deposited by evaporation or spraying of metal oxides on the plate of glass, or by deposition of a resin loaded with a black powder. When the sheet of glass bearing the material having a high optical density and the covers are brought together, good alignment of the separations between the colour elements and the lines of material having a high optical density is ensured.

The sheet of glass may receive a metal surface for screening of electromagnetic shielding type (for the sake of electromagnetic compatibility, EMC). Such a metal grille closes off a metal cage of the unit bearing the screen, and thus forms a Faraday cage which protects the contents of the unit.

It may be given a non-reflective treatment.

It is connected to the support 100, on the face thereof bearing the LEDs 101, . . . 10x, for example by an optical adhesive which polymerizes, between the LEDs and the covers, or if the covers have been placed on the LEDs initially, between the covers and the glass.

The support 100 comprises TFTs or a CMOS circuit or another microelectronics substrate, and is attached to a mechanical framework, forming a frame which also bears the electronic boards for controlling the diodes.

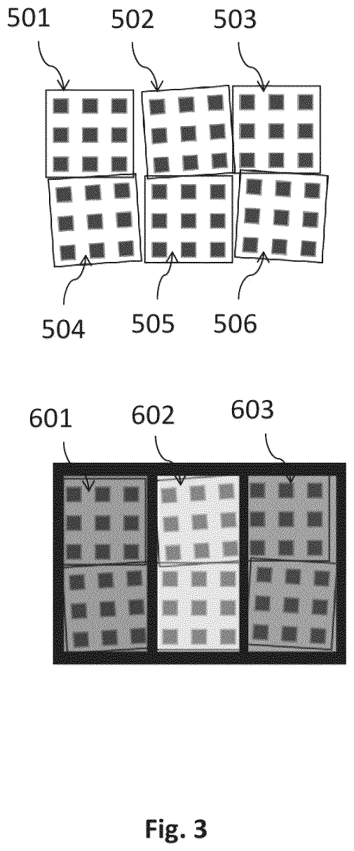

FIG. 3 shows an embodiment wherein the micro-LEDs are borne by square supports of small size which can hold 9 micro-LEDs, in a 3×3 arrangement. It is chosen to use covers formed of active plates 601 and 602 (with a change in the wavelength of the light, by photoluminescence) and a passive plate 603 (without photoluminescence) each having Lambertian angular emission, having a rectangular shape and a dimension selected to cover two squares each corresponding to 9 micro-LEDs, placed one beside the other, so as to thus form three sources of juxtaposed coloured light as in the structure in the top part of FIG. 1. Thus, use was made of 6 supports 501-506 for three plates 601-603. In such a case, the fact that the supports are not positioned on an underlying support, in a totally controlled manner, to within a few angular degrees, or to within a few micrometres in translation, is counteracted visually once the plates 601-603 are put in place, since the angular imperfections are masked by the plates.

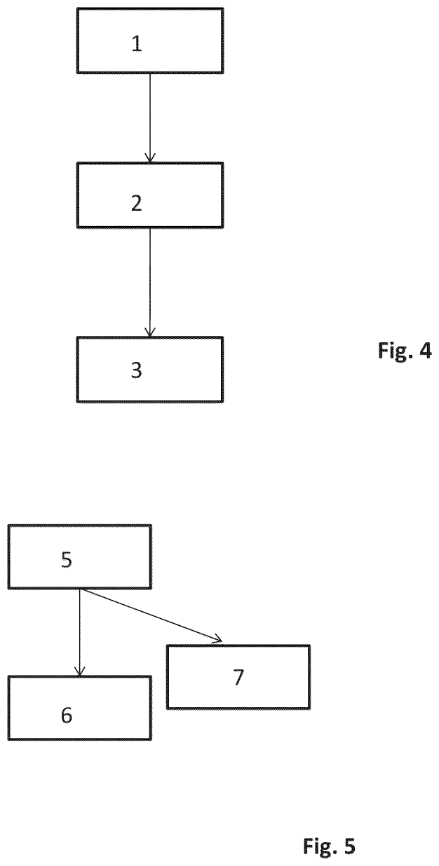

FIG. 4 shows a method according to the invention. During a step 1, a liquid crystal screen, or a screen with electroluminescent diodes with emissive technology is removed, this screen being present in the instrument panel of an aircraft, and needing to be replaced, as a result of obsolescence or breakdown, or evolution proposed to the operator.

A step 2 consists in identifying a configuration of a screen having micro-LEDs in accordance with the principles of the invention, which offers the same resolution as the screen removed, regardless of the technology on which the latter is based.

To this end, there is a stock of rectangular or square micro-LED supports comprising micro-LEDs arranged on a surface of the support.

The support has dimensions in the two dimensions of the plane. Moreover, the micro-LEDs are arranged on the surface of the support with a given known density. On this basis, it is chosen, according to the desired size of the pixels, to dimension the coloured plates which will be placed over the micro-LEDs so that they cover a suitable number of micro-LEDs, taking the form of a rectangle of n×m micro-LEDs, with at least n or m being greater than or equal to 2.

In step 3, the LCD screen is replaced with the micro-LED screen. The latter receives the same video stream as the previous screen, which is typically a digital video stream transferred by a data bus, for example in LVDS format, with a resolution of 1920×1080 pixels, and a refresh rate of 50 to 60 Hz.

FIG. 5 shows another method according to the invention. Note also that the structure which is proposed also makes it possible to compensate for any defective micro-LEDs, since the micro-LEDs are grouped together in groups of several micro-LEDs, and that it is thus possible to compensate for the breakdown of a micro-LED (detected by mapping the luminance to detect anomalies) by imposing a greater light on the micro-LEDs placed under the same plate, by the command transmitted to them, or indeed by activating hitherto unused micro-LEDs which have been kept in reserve to be used in the event of a breakdown.

Thus, during a step 5 of mapping various similar display systems of a suite of display systems, those which need a modification of the display because of the breakdown of certain micro-LEDs are identified, and on the basis of this diagnostic, the command applied to the screens which are not defective is maintained unchanged (step 6) and the command applied to the screens for which it has been found that one or more micro-LEDs are defective is modified (step 7) so as to compensate, using neighbouring micro-LEDs which are under the same plate, for the loss of light intensity of the one or more defective micro-LEDs.

In general, blue micro-LEDs have been envisaged in the text as constituent elements of the system, but violet micro-LEDs are used in a variant. Moreover, the sheet of glass 200 may be made of another material that allows the wavelengths in question to pass through, in particular a flexible material, of polymeric nature.

The screens described offer a wide range of colours by additive colour synthesis, for each pixel, of three colour sources, one blue, another red and the third green, each constituting a sub-pixel. However, the screen may alternatively be a monochrome screen of a flight control unit, wherein each pixel comprises a single sub-pixel, with a single colour, which may be green. In this case and in one embodiment, use is again made of blue micro-LEDs, this time adding to the latter a green phosphor or a green quantum dot in a cover common to several micro-LEDs for the conversion of wavelength and diffusion. In this case, there is a single type of pixel composed of a certain number of blue micro-LEDs and of a green fluorescent element, layer or plate, covering the group of micro-LEDs, and acting as a single light source, owing to the diffuse nature of the light that it relays.

The plates forming a cover have been described as being formed of synthetic resin or polymer, with the inclusion of a dispersion of quantum dots or of dispersing powder in the volume forming a layer of a certain thickness, the resin remaining in place for the service life of the product. Alternatively, the cover function may be attained by deposition of the quantum dots or of the dispersing powder on a flat surface—the surface of the sheet of glass—in a solvent which evaporates after deposition, and which thus leaves only a thin deposit of small thickness, as the solvent has disappeared. The deposit is flat and homogeneous.

Alternatively, the plates forming a cover are formed by deposition of phosphor granules on the sheet of glass. The deposit is flat and homogeneous.

1. A screen based on emissive pixels for an aircraft cockpit, comprising a flat substrate bearing a plurality of electroluminescent diodes in the same emission spectrum and wherein each pixel is made up of at least one compact group of several of said electroluminescent diodes, the screen wherein in a pixel of the screen, the electroluminescent diodes of the group of diodes are covered with a layer forming a cover common to said electroluminescent diodes of said group of diodes and relaying a diffuse light, with or without photoluminescence, in response to the emission of light by the electroluminescent diodes of the group.

2. The screen based on emissive pixels according to claim 1, wherein the layer comprises quantum dots such that the light diffused has a greater wavelength than the light received from the electroluminescent diodes and that the layer has an angularly extensive light emission.

3. The screen based on emissive pixels according to claim 1, wherein the pixel comprises several groups of electroluminescent diodes, and for each group of diodes of the pixel, a layer with a specific colorimetric property covers the electroluminescent diodes of said group, forming a cover specific to each of the groups.

4. The screen based on emissive pixels according to claim 3, wherein the layer of one of said several groups of diodes comprises a diffusing load and is without the property of photoluminescence.

5. The screen based on emissive pixels according to claim 1, wherein the electroluminescent diodes are diodes based on gallium nitride, referred to as micro-LEDs, having identical emission spectrums.

6. The screen based on emissive pixels according to claim 1, wherein each group of diodes is formed by bringing together rectangular substrates of electroluminescent diodes comprising diodes in several rows of diodes.

7. The screen based on emissive pixels according to claim 1, wherein a material having a high optical density is placed between the groups of diodes.

8. The screen based on emissive pixels according to claim 1, wherein the layer encapsulates the diodes, or is placed on a layer of glass adhesively bonded to the diodes.

9. A method for replacement of a display screen of a cockpit of an aircraft, comprising a step of removing a screen based on liquid crystals with backlighting, and a step of replacing said screen with a screen of resolution identical to the resolution of said screen based on liquid crystals, wherein the screen of identical resolution is selected as a screen based on emissive pixels according to claim 1, the number of electroluminescent diodes in the groups being selected such that, given the number of groups, the size of the pixel is the size of the pixels of the screen based on liquid crystals with backlighting.
